(19) United States
(12) Patent Application Publication
(10) Pub. No.: US 2025/0004337 A1
(43) Pub. Date: Jan. 2, 2025

(54) DISPLAY DEVICE AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Koji KUSUNOKI, Isehara (JP); Masahiro KATAYAMA, Isehara (JP); Rai SATO, Tochigi (JP)

(21) Appl. No.: 18/710,360

(22) PCT Filed: Nov. 16, 2022
(86) PCT No.: PCT/IB2022/061010

§ 371 Date: May 15, 2024

(30) Foreign Application Priority Data
Nov. 26, 2021 (JP) 2021-191975

(51) Int. Cl. G02F 1/1362; G02F 1/133; G02F 1/1333; G02F 1/1335; G02F 1/13357; G02F 1/1368; H01L 25/16; H01L 27/12

(52) U.S. Cl. CPC G02F 1/136286; G02F 1/13306; G02F 1/13334; G02F 1/133512; G02F 1/133603; G02F 1/133614; G02F 1/1368; H01L 27/1248; G02F 2201/40; G02F 2202/36; H01L 25/167

(57) ABSTRACT

A display device with a high aperture ratio is provided. A step caused by a contact hole (50) for electrically connecting a wiring (33) and a pixel electrode (41) to each other is eliminated by being filled with an organic insulating layer (52), and a top surface of the pixel electrode is made flat to form an alignment film (45a) so that an alignment defect of a liquid crystal layer (40) is reduced. In addition, a light-transmitting material is used for the wiring (33) exposed to a bottom portion of the contact hole (50). Accordingly, an effective display region of a liquid crystal device can be increased. That is, the display device can have a high aperture ratio.

### TECHNICAL FIELD

One embodiment of the present invention relates to a liquid crystal display device and an electronic device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor or the like), an input/output device (e.g., a touch panel or the like), a driving method thereof, and a manufacturing method thereof.

### BACKGROUND ART

In recent years, the definition of display devices has been increased. When a high-definition display device having a pixel count of 4K2K (3840×2160), 8K4K (7680×4320), or the like is mounted on a television device, digital signage, a tablet terminal, a smartphone, or the like, recognizability is improved, so that convenience can be increased.

In addition, attention has been focused on a technique for using a metal oxide exhibiting semiconductor characteristics for a transistor, instead of a silicon semiconductor. Note that in this specification, a metal oxide exhibiting semiconductor characteristics is referred to as an oxide semiconductor. For example, Patent Document 1 and Patent Document 2 disclose a technique in which a transistor using zinc oxide or an In—Ga—Zn-based oxide as an oxide semiconductor is manufactured and used for a switching element or the like of a pixel of a display device.

### REFERENCE

### Patent Document

[Patent Document 1] Japanese Published Patent Application No. 2007-123861
[Patent Document 2] Japanese Published Patent Application No. 2007-96055

### SUMMARY OF THE INVENTION

### Problems to be Solved by the Invention

A display device using a liquid crystal device can display a high-definition image by increasing a pixel count per unit area. In the case of an active-matrix display device, a transistor, a capacitor, a wiring, and the like in addition to a liquid crystal device need to be provided in a pixel.

When the pixel count per unit area is increased, an area occupied by components that do not transmit light is relatively large in the pixel. That is, an aperture ratio (the proportion of an effective display region in a pixel) is decreased. Thus, in a transmissive liquid crystal device or the like, the light intensity of a backlight needs to be increased to display a clear image, and power consumption is increased.

Thus, one object of one embodiment of the present invention is to provide a display device with a high aperture ratio. Another object is to provide a display device with low power consumption. Another object is to provide a high-definition display device. Another object is to provide a highly reliable display device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention relates to a liquid crystal display device with a high aperture ratio.

One embodiment of the present invention is a display device including a first transistor, a first conductive layer, a second conductive layer, a third conductive layer, a first insulating layer, a second insulating layer, an alignment film, and a liquid crystal layer. The first transistor is electrically connected to the first conductive layer. The first insulating layer is provided over the first transistor and the first conductive layer. The first insulating layer includes an opening portion penetrating the first insulating layer in a region overlapping the first conductive layer. The second conductive layer is provided to be in contact with a top surface of the first insulating layer, a side surface of the opening portion, and the first conductive layer exposed to a bottom portion of the opening portion. The second insulating layer is provided to be in contact with the second conductive layer to fill a step caused by the opening portion. The third conductive layer is provided to be in contact with the second conductive layer and the second insulating layer. The alignment film is provided over the first insulating layer, the second conductive layer, and the third conductive layer. The liquid crystal layer is provided over the alignment film. The first conductive layer, the second conductive layer, the third conductive layer, the first insulating layer, and the second insulating layer each have a property of transmitting visible light.

A light-blocking layer can be provided over the liquid crystal layer. In a plan view, a mode can be employed in which the light-blocking layer includes a region overlapping the first transistor and does not include a region overlapping the opening portion.

The first conductive layer can be a metal oxide, and the first conductive layer can be electrically connected to a semiconductor layer of the first transistor through a metal layer.

The first conductive layer and the metal layer can work as one electrode of a capacitor.

It is preferable that the semiconductor layer of the first transistor be a metal oxide.

The display device can include a backlight device, and a light source of the backlight device can include a light-emitting diode.

Light emitted from the light-emitting diode can be blue light, and a color conversion layer can be provided over the light-emitting diode, and the backlight device can emit white light. The color conversion layer can include a quantum dot.

A structure can be employed in which the light-emitting diode is electrically connected to a second transistor and a driver circuit for driving the second transistor is provided in a position overlapping the light-emitting diode.

The second transistor can include a metal oxide in a channel formation region, and a transistor included in the driver circuit can include silicon in a channel formation region.

It is preferable that the light-emitting diode be a mini LED or a micro LED.

Note that in this specification, a module in which a connector such as an FPC (Flexible printed circuit) or a TCP (Tape Carrier Package) is attached to a display portion, a module in which a printed wiring board is provided at the tip of a TCP, or a module in which an IC (integrated circuit) is directly mounted by a COG (Chip On Glass) method on a substrate where a display element is formed is also included in a display device in some cases.

### Effect of the Invention

One embodiment of the present invention can provide a display device with a high aperture ratio. Alternatively, a display device with low power consumption can be provided. Alternatively, a high-definition display device can be provided. Alternatively, a highly reliable display device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are diagrams illustrating a pixel.

FIG. 2A and FIG. 2B are diagrams illustrating the pixel.

FIG. 3A and FIG. 3B are diagrams illustrating the pixel.

FIG. 4A and FIG. 4B are diagrams illustrating the pixel.

FIG. 5A and FIG. 5B are diagrams illustrating a stack of a liquid crystal display device and a backlight device.

FIG. 6A is a block diagram of the liquid crystal display device. FIG. 6B is a diagram illustrating a circuit of the pixel of the liquid crystal display device.

FIG. 7A and FIG. 7B are block diagrams of the backlight device. FIG. 7C and FIG. 7D, and FIG. 7E1 to FIG. 7E3 are diagrams illustrating circuits of light-emitting units.

FIG. 8A to FIG. 8C are diagrams illustrating the liquid crystal display device.

FIG. 9 is a cross-sectional view illustrating the liquid crystal display device.

FIG. 10 is a cross-sectional view illustrating a stack of the liquid crystal display device and the backlight device.

FIG. 11A to FIG. 11D are diagrams each illustrating a transistor.

FIG. 12A to FIG. 12E are diagrams illustrating electronic devices.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that the term “film” and the term “layer” can be interchanged with each other depending on the case or circumstances. For example, the term “conductive layer” can be replaced with the term “conductive film.” For another example, the term “insulating film” can be replaced with the term “insulating layer.”

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for a semiconductor layer of a transistor, the metal oxide is referred to as an oxide semiconductor in some cases. That is, in the case where an OS transistor is stated, the OS transistor can be also referred to as a transistor including a metal oxide or an oxide semiconductor.

In addition, in this specification and the like, a metal oxide containing nitrogen is also collectively referred to as a metal oxide in some cases. Furthermore, a metal oxide containing nitrogen may be referred to as a metal oxynitride.

### Embodiment 1

In this embodiment, a display device according to one embodiment of the present invention will be described.

A display device according to one embodiment of the present invention relates to a liquid crystal display device with a high aperture ratio. A liquid crystal device (also referred to as a liquid crystal element) has a structure where a liquid crystal layer sandwiched between a pair of alignment films is sandwiched between a pair of electrodes. The alignment film has a function of uniformly arranging liquid crystal molecules. However, when the alignment film is formed in a region where a step occurs, an alignment defect sometimes occurs in the liquid crystal layer over the region.

In a region where one electrode of the liquid crystal device is connected to a wiring, the alignment film is formed along a step caused by a contact hole. Thus, an alignment defect is likely to occur particularly in the liquid crystal layer that is provided over the region and its vicinity. A region where an alignment defect occurs decreases a display contrast due to light leakage or the like; thus, the region is preferably covered with a light-blocking layer. Meanwhile, an increase in the area of the light-blocking layer results in a decrease in the aperture ratio.

In one embodiment of the present invention, the step caused by the contact hole is eliminated by being filled with an insulating layer so that the alignment defect of the liquid crystal layer is reduced. In addition, a wiring that is exposed to a bottom portion of the contact hole is formed using a light-transmitting material. Accordingly, an effective display region of the liquid crystal device can be increased. That is, the display device can have a high aperture ratio.

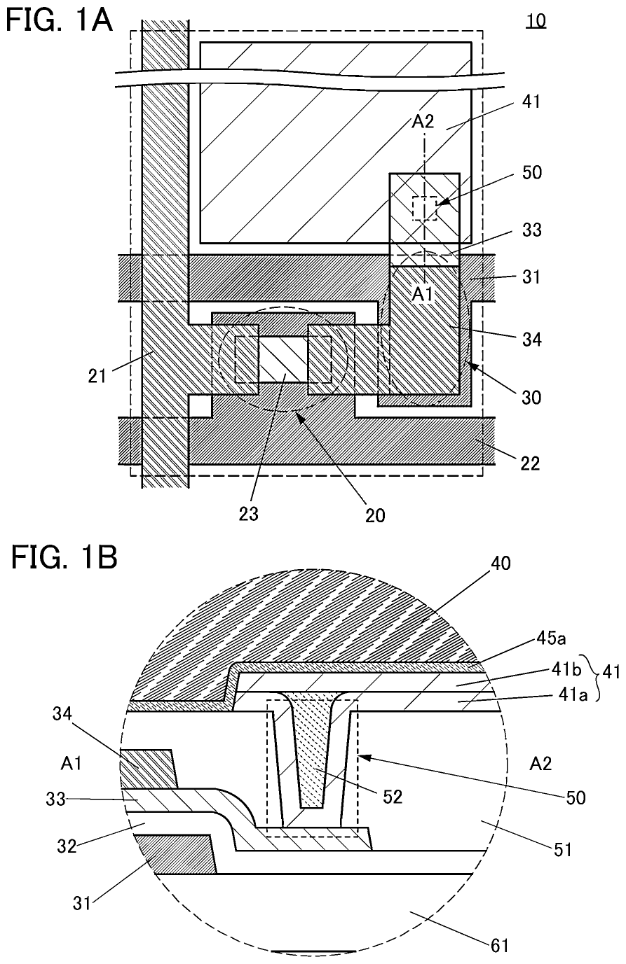

FIG. 1A is a top view of a pixel included in a liquid crystal display device according to one embodiment of the present invention, and FIG. 1B is an enlarged view of part of a cross section along a line segment A1-A2 illustrated in FIG. 1A. Note that for clarity, some components are not illustrated in FIG. 1A.

A pixel 10 includes a transistor 20, a capacitor 30, and a liquid crystal device.

The transistor 20 includes a wiring 21, a wiring 22, a semiconductor layer 23, and a wiring 34 as components. An oxide semiconductor (a metal oxide), amorphous silicon, microcrystalline silicon, polycrystalline silicon, or the like can be used for the semiconductor layer 23. The semiconductor layer 23 is electrically connected to the wiring 21 and the wiring 34.

The wiring 21 functions as one of a source and a drain, the wiring 22 functions as a gate, and the wiring 34 functions as the other of the source and the drain. The wiring 21, the wiring 22, and the wiring 34 are preferably provided using a low-resistance conductive layer. A metal layer of titanium, tantalum, tungsten, chromium, aluminum, or the like, or an alloy layer containing one or more of these metals can be used for the conductive layer, for example. Alternatively, the conductive layer may be a stack of two or more selected from the metal layers and the alloy layers containing the above metals. Note that although FIG. 1A illustrates an example where the transistor 20 is a back gate transistor, the transistor 20 may be a top-gate transistor, a self-aligned transistor, or the like.

The capacitor 30 is a MIM (Metal-Insulator-Metal) capacitor, which includes a wiring 31, an insulating layer 32, a wiring 33, and the wiring 34 as components. The wiring 31 functions as one electrode of the capacitor 30, the insulating layer 32 functions as a dielectric layer, and the wiring 33 and the wiring 34 function as the other electrode of the capacitor 30. Here, the wiring 31 can be formed in the same step as the wiring 22. The insulating layer 32 also functions as a gate insulating film of the transistor 20.

The wiring 33 also functions as a wiring that is connected to a pixel electrode 41 (a conductive layer 41a). In addition, the wiring 33 has a region overlapping the wiring 34, and the wiring 33 and the wiring 34 are electrically connected to each other. In one embodiment of the present invention, a region where the wiring 33 and the pixel electrode 41 (the conductive layer 41a) are connected to each other is used as an effective region of the liquid crystal device; thus, a light-transmitting conductive layer (a light-transmitting conductive film) is used for the wiring 33.

The light-transmitting conductive film preferably contains one or more kinds selected from indium, zinc, and tin. Specific examples include metal oxides such as an In oxide, an In—Sn oxide (also referred to as ITO: Indium Tin Oxide), an In—Zn oxide, an In—W oxide, an In—W—Zn oxide, an In—Ti oxide, an In—Sn—Ti oxide, an In—Sn—Si oxide, a Zn oxide, and a Ga—Zn oxide. Alternatively, an oxide semiconductor having reduced resistance by containing an impurity element in a metal oxide that also functions as the semiconductor layer of the transistor may be used. The oxide semiconductor with reduced resistance can be regarded as an oxide conductor (OC).

For example, as for an oxide conductor, oxygen vacancies are formed in an oxide semiconductor and hydrogen is added to the oxygen vacancies, so that a donor level is formed in the vicinity of the conduction band. The formation of the donor level in the oxide semiconductor increases the conductivity of the oxide semiconductor, so that the oxide semiconductor becomes a conductor.

Note that the oxide semiconductor has a large energy gap (e.g., an energy gap greater than or equal to 2.5 eV), and thus has a property of transmitting visible light. In addition, the oxide conductor is an oxide semiconductor having a donor level in the vicinity of the conduction band, as described above. Therefore, the influence of absorption due to the donor level is small in the oxide conductor, and the oxide conductor has a property of transmitting visible light comparable to that of the oxide semiconductor.

For example, in the case where an oxide semiconductor is used for the semiconductor layer 23 of the transistor 20, the wiring 33 can be a layer that is formed in the same step as the semiconductor layer 23 and has reduced resistance.

The liquid crystal device has a structure where a liquid crystal layer sandwiched between a pair of alignment films is sandwiched between a pair of electrodes. FIG. 1B illustrates the pixel electrode 41 (conductive layers 41a and 41b) as one of the electrodes, an alignment film 45a as one of the alignment films, and a liquid crystal layer 40. The light-transmitting conductive film can be used for the pixel electrode 41.

An insulating layer 51 is provided over the transistor 20, the capacitor 30, and the wiring 33 as a planarization layer, and an opening portion 50 (a contact hole) is formed in a region overlapping the wiring 33. The conductive layer 41a is formed to be in contact with the wiring 33 that is exposed to a side surface of the opening portion 50 and a bottom portion of the opening portion 50.

Here, the opening portion 50 has a step shape, and the step is not eliminated only by formation of the conductive layer 41a. Since the insulating layer 51 is formed comparatively thick as the planarization layer, it is difficult to eliminate the step even when the film thickness of the conductive layer 41a is made large. Therefore, as illustrated in FIG. 1B, an insulating layer 52 is formed to be in contact with the conductive layer 41a so that a step caused by the opening portion 50 is eliminated.

The insulating layer 52 is preferably formed using an organic material having a property of transmitting visible light. As the organic material, a photosensitive organic resin is preferably used, and for example, a photosensitive resin composition containing an acrylic resin is used. Note that in this specification and the like, an acrylic resin refers to not only a polymethacrylic acid ester or a methacrylic resin but also all the acrylic polymer in a broad sense in some cases. With the use of a photosensitive organic material, the insulating layer 52 can be formed in a desired region by using a photolithography step.

Alternatively, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used for the insulating layer 52. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the insulating layer 52.

Then, by forming the conductive layer 41b over the conductive layer 41a and the insulating layer 52, the pixel electrode 41 having a flat top surface can be formed. Thus, the flat alignment film 45a can be formed over the pixel electrode 41.

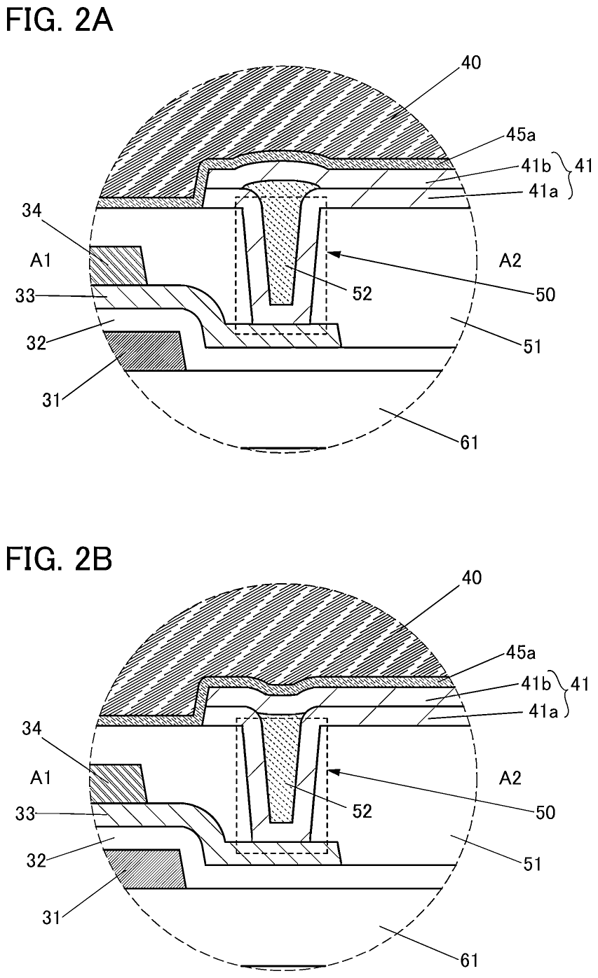

Note that as illustrated in FIG. 1B, the conductive layer 41a provided over the insulating layer 51 and the insulating layer 52 are further preferably formed so that their top surfaces are level with each other. Note that the top surface of the insulating layer 52 may have a convex shape as illustrated in FIG. 2A, for example, as long as an alignment defect of liquid crystal molecules does not occur. Alternatively, the top surface of the insulating layer 52 may have a concave shape as illustrated in FIG. 2B.

Such a structure can eliminate the step caused by the opening portion 50; thus, an alignment defect of the liquid crystal layer 40 that is provided over the region and its vicinity can be prevented. Accordingly, the effective display region of the liquid crystal device can be increased.

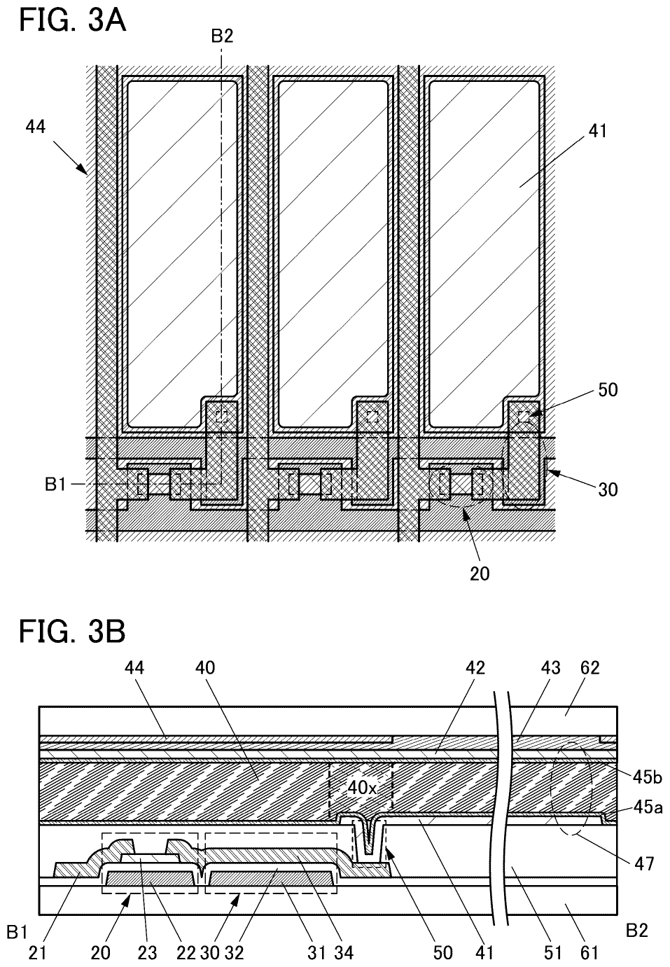

FIG. 3A and FIG. 3B illustrate a conventional example, which is a comparative example where one embodiment of the present invention is not used. FIG. 3A is a top view of a plurality of adjacent pixels, and FIG. 3B is a cross-sectional view along a line segment B1-B2 illustrated in FIG. 3A.

The same reference numerals are used to denote components common to those in FIG. 1A and FIG. 1B, and an alignment film 45b, a counter electrode 42, a coloring layer 43, a light-blocking layer 44, a substrate 62, and the entire liquid crystal device (a liquid crystal device 47) are illustrated as components that are illustrated in neither FIG. 1A nor FIG. 1B. Note that as to components above the pixel electrode 41, FIG. 3A illustrates only the light-blocking layer 44 for clarity.

The alignment film 45b corresponds to the other of a pair of alignment films included in the liquid crystal device 47. The counter electrode 42 corresponds to the other of a pair of electrodes included in the liquid crystal device 47. The coloring layer 43 is a color filter for color display and can be formed using a resin layer or the like in which a pigment is dispersed. The light-blocking layer 44 has a function of preventing color mixing and changes in transistor characteristics due to light irradiation and can be formed using a black resin layer or the like.

As illustrated in FIG. 3B, the alignment film 45a is formed along a step caused by the opening portion 50 in the conventional example; thus, alignment disorder of liquid crystal molecules occurs over the opening portion 50 and its vicinity, and an alignment defect region 40x is generated in the liquid crystal layer 40. Therefore, the light-blocking layer 44 needs to be provided to overlap the alignment defect region 40x. That is, an opening portion of the light-blocking layer 44 is reduced, so that an aperture ratio is decreased.

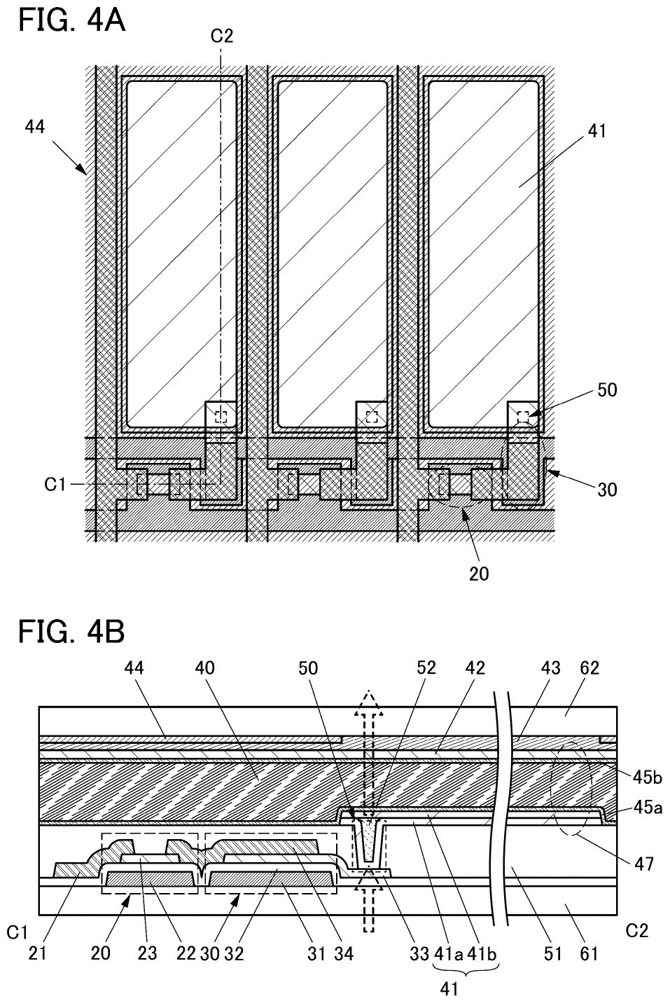

FIG. 4A and FIG. 4B are diagrams each illustrating one embodiment of the present invention. FIG. 4A is a top view of a plurality of adjacent pixels, and FIG. 4B is a cross-sectional view along a line segment C1-C2 illustrated in FIG. 4A. The same reference numerals are used to denote components common to those in FIG. 1A and FIG. 1B, and FIG. 3A and FIG. 3B. Note that as to components above the pixel electrode 41, FIG. 4A illustrates only the light-blocking layer 44 for clarity. Note that although FIG. 4A illustrates stripe arrangement as an example, mosaic arrangement or delta arrangement may be employed.

As illustrated in FIG. 4B, the alignment film 45a becomes flat even over the opening portion 50 by elimination of a step caused by the opening portion 50, so that no alignment defect region is generated in the liquid crystal layer 40 over the opening portion 50 and its vicinity. In other words, the light-blocking layer 44 over the opening portion 50 and its vicinity that is required in the conventional example becomes unnecessary.

In addition, a region overlapping the opening portion 50 has a light-transmitting property because a light-transmitting conductive film is used for the wiring 33 that is connected to the pixel electrode 41. Accordingly, an effective display region of the liquid crystal device 47 can be increased. In other words, an aperture ratio can be increased.

Note that in the above structure, a plurality of light-transmitting layers having different refractive indices are placed over the opening portion 50 and its vicinity, so that unintended light refraction, scattering, or reflection sometimes occurs and decreases a display contrast. Accordingly, the opening portion 50 and the wiring 33 that overlaps the opening portion 50 are preferably formed to have as narrow width as possible.

For example, in a display device whose diagonal size is less than or equal to 10 inches, the width of the bottom of the opening portion 50 when seen from a top surface is less than or equal to 3 μm, preferably less than or equal to 2 μm, further preferably less than or equal to 1 μm. In addition, the width of the wiring 33 is less than or equal to twice, preferably less than or equal to 1.5 times as large as the width of the bottom of the opening portion 50.

In order to form the opening portion 50 and the wiring 33 having such sizes, it is preferable to use, for example, a stepper for a large-sized substrate (e.g., a stepper compatible with a G6 glass substrate) that has a L/S (line and space) resolution lower than or equal to 1.5 μm, preferably lower than or equal to 1.2 μm and an overlay accuracy lower than or equal to ±0.25 μm, preferably lower than or equal to ±0.23 μm.

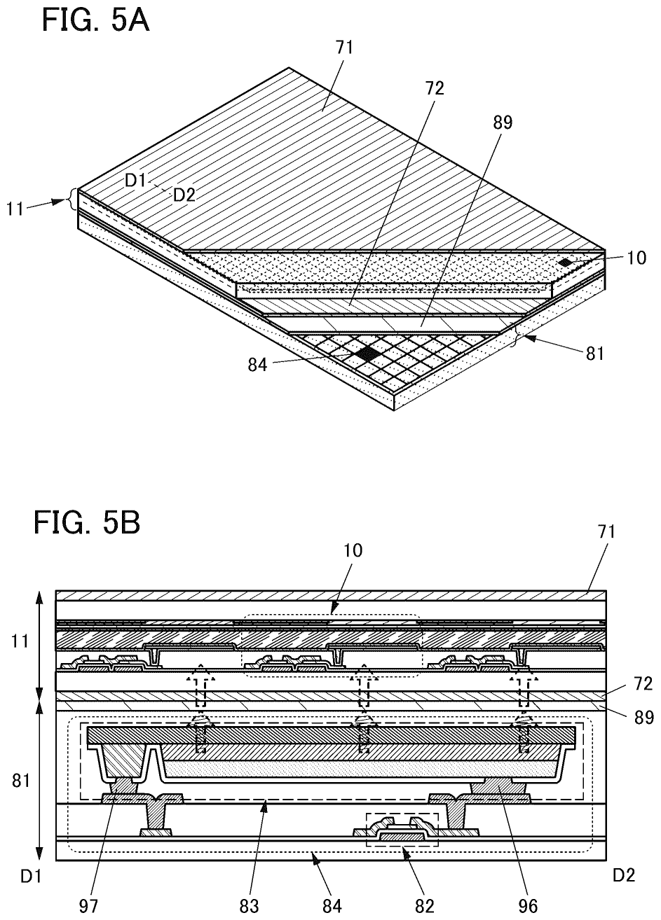

FIG. 5A is a perspective view illustrating an example of a stacked-layer structure where the liquid crystal display device and a backlight device are combined, and FIG. 5A illustrates each layer that is partly cut out. In addition, FIG. 5B is a cross-sectional view that corresponds to a cross section along a line segment D1-D2 illustrated in FIG. 5A. Note that the stacked-layer structure is an example, and a layer having another function may be incorporated in the stack.

A liquid crystal display device 11 includes a plurality of pixels 10. A polarizing plate 71 is placed on a top surface of the liquid crystal display device 11, and a polarizing plate 72 is placed on a bottom surface of the liquid crystal display device 11.

The backlight device 81 has a structure where a plurality of light-emitting units 84 are arranged in a matrix. The light-emitting unit 84 includes a light-emitting diode (LED) 83 and a transistor 82. One light-emitting unit 84 has a region overlapping the plurality of pixels 10.

The transistor 82 is a component of a circuit for active driving of the light-emitting diode 83. An oxide semiconductor (a metal oxide), amorphous silicon, microcrystalline silicon, polycrystalline silicon, or the like can be used for a semiconductor layer of the transistor 82. Note that although FIG. 5B illustrates an example where the transistor 82 is a back gate transistor, the transistor 82 may be a top-gate transistor, a self-aligned transistor, or the like.

Note that passive driving may be employed for the light-emitting diode 83. In that case, the transistor 82 can be made unnecessary.

As the light-emitting diode 83, it is preferable to use a micro LED whose diameter or one side is formed to be less than or equal to 50 μm or a mini LED whose diameter or one side is formed to be greater than 50 μm and less than or equal to 200 μm, for example.

Note that although FIG. 5B illustrates a mode in which a wiring included in the backlight device 81 is directly bonded to an electrode included in the light-emitting diode 83, the wiring may be directly bonded to the electrode through solder, a conductive resin, an anisotropic conductive resin, an anisotropic conductive film, or the like.

The use of the plurality of light-emitting units 84 arranged in a matrix in the backlight device 81 enables fine control by local dimming, so that an ultra-sharp image with a high contrast can be displayed. In addition, the light-emitting diode 83 does not always emit light and luminance can be adjusted in accordance with lightness and darkness of display, so that power consumption can be reduced.

A color conversion layer 89 can be provided at the top of the backlight device 81. The color conversion layer 89 preferably includes a phosphor or a quantum dot (QD). In particular, in the case of using a quantum dot, it is possible to obtain light emission having an emission spectrum with narrow peak width and high color purity.

For example, white light can be obtained when the light-emitting diode 83 is a blue LED that emits blue light and a quantum dot that converts blue light into red light and green light is used for the color conversion layer 89. Note that in the case where a white LED that emits white light is used as the light-emitting diode 83, the color conversion layer 89 may be made unnecessary.

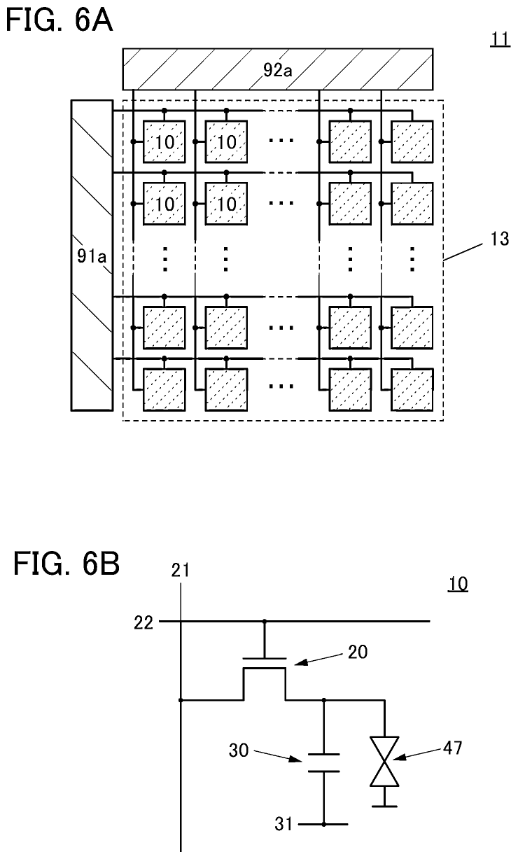

FIG. 6A is a block diagram illustrating the liquid crystal display device 11 according to one embodiment of the present invention. The liquid crystal display device 11 includes a pixel array 13, a gate driver 91a, and a source driver 92a. The pixel array 13 includes the pixels 10 arranged in a column direction and a row direction.

A sequential circuit such as a shift register can be used for each of the gate driver 91a and the source driver 92a. The gate driver 91a and the source driver 92a can be monolithically formed over a substrate over which circuits included in the pixels 10 are formed.

Alternatively, an IC chip provided with the gate driver 91a and an IC chip provided with the source driver 92a may be connected to the pixel array 13 by a COF (chip on film) method, a COG (chip on glass) method, a TCP (tape carrier package) method, or the like.

Note that although an example where the gate driver 91a is placed on one side of the pixel array 13 is illustrated, two gate drivers 91a may be placed with the pixel array 13 therebetween to divide driving rows.

FIG. 6B is an example of a circuit diagram of the pixel 10. One of a source and a drain of the transistor 20 is electrically connected to one electrode of the capacitor 30 and one electrode of the liquid crystal device 47. A gate of the transistor 20 is electrically connected to the wiring 22. The other of the source and the drain of the transistor 20 is electrically connected to the wiring 21. Note that the other electrode of the capacitor 30 is electrically connected to the wiring 31 that supplies a fixed potential. The other electrode of the liquid crystal device 47 is electrically connected to a fixed potential line.

Here, the wiring 21 functions as a source line and can be electrically connected to the source driver 92a. The wiring 22 functions as a gate line and can be electrically connected to the gate driver 91a.

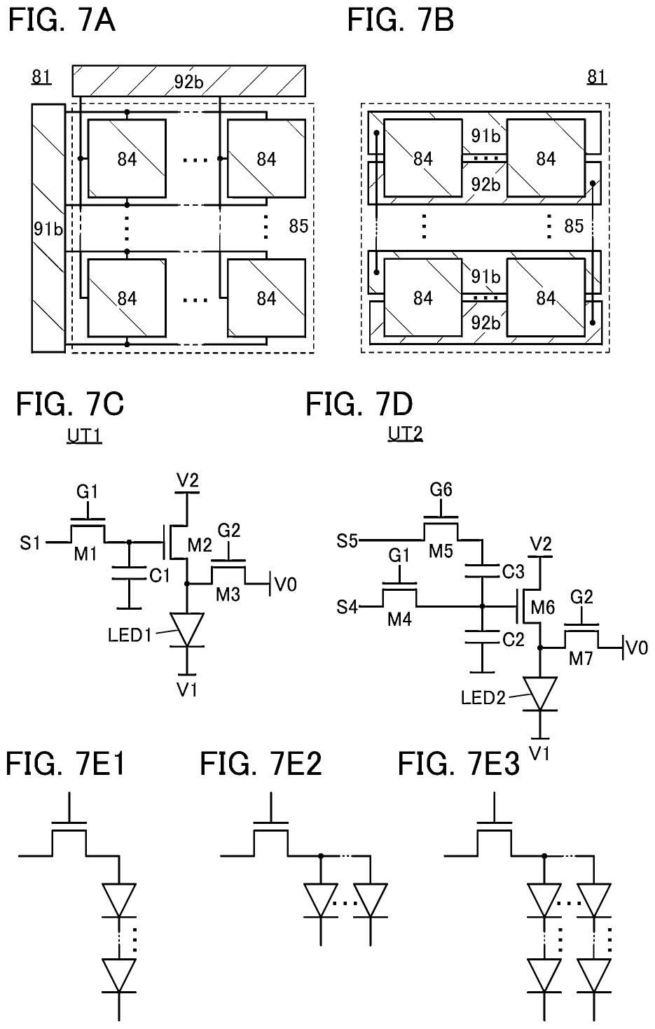

FIG. 7A is a block diagram illustrating the backlight device 81 illustrated in FIG. 5A and FIG. 5B. The backlight device 81 includes an LED array 85, a gate driver 91b, and a source driver 92b. The LED array 85 includes the light-emitting units 84 placed in a row direction and a column direction.

A sequential circuit such as a shift register can be used for each of the gate driver 91b and the source driver 92b. The gate driver 91b and the source driver 92b can be monolithically formed over a substrate over which circuits included in the light-emitting units 84 are formed.

Alternatively, an IC chip provided with the gate driver 91b and an IC chip provided with the source driver 92b may be connected to the LED array 85 by a COF (chip on film) method, a COG (chip on glass) method, a TCP (tape carrier package) method, or the like.

Note that although an example where the gate driver 91b is placed on one side of the pixel array 13 is illustrated, two gate drivers 91b may be placed with the LED array 85 therebetween to divide driving rows.

In addition, the gate drivers 91b and the source drivers 92b can be also placed in regions overlapping the LED array 85, as illustrated in FIG. 7B. Such a structure can shorten wiring length between the gate driver 91b and the source driver 92b, and the light-emitting unit 84 and can reduce wiring resistance and wiring capacitance. Accordingly, a high-speed operation and a reduction in power consumption can be achieved. Furthermore, the backlight device 81 can be made small because its bezel can be narrowed.

In the structure in FIG. 7B, the gate driver 91b and the source driver 92b can be each formed using a transistor including silicon in a channel formation region (hereinafter a Si transistor), for example. In addition, transistors (the transistor 82 and the like) included in the LED array 85 can be each formed using a transistor including an oxide semiconductor in a channel formation region (hereinafter an OS transistor).

Polycrystalline silicon, which can be formed over a glass substrate or the like, is preferably used for the Si transistor used here. The Si transistor, which has high mobility, is suitable for a component of a circuit that requires a high-speed operation. In addition, the OS transistor, which has comparatively high breakdown voltage, is suitable for a drive transistor of an LED that feeds large current.

Note that although FIG. 7B illustrates a structure where the gate driver 91b and the source driver 92b are divided and placed, the number of divisions is not limited and can be set as appropriate. In addition, although FIG. 7B illustrates an example where the gate driver 91b and the source driver 92b are not divided in a horizontal direction, the gate driver 91b and the source driver 92b may be divided in a horizontal direction.

FIG. 7C illustrates an example of a circuit UT1 that can be applied to the light-emitting unit 84. The circuit UT1 includes a light-emitting diode LED1 (corresponding to the light-emitting diode 83), a transistor M1, a transistor M2 (corresponding to the transistor 82), a transistor M3, and a capacitor C1.

A gate of the transistor M1 is electrically connected to a wiring G1, one of a source and a drain of the transistor M1 is electrically connected to a wiring S1, and the other of the source and the drain of the transistor M1 is electrically connected to one electrode of the capacitor C1 and a gate of the transistor M2. One of a source and a drain of the transistor M2 is electrically connected to a wiring V2, and the other of the source and the drain of the transistor M2 is electrically connected to an anode of the light-emitting diode LED1 and one of a source and a drain of the transistor M3. A gate of the transistor M3 is electrically connected to a wiring G2, and the other of the source and the drain of the transistor M3 is electrically connected to a wiring V0. A cathode of the light-emitting diode LED1 is electrically connected to a wiring V1.

A constant potential is supplied to each of the wiring V1 and the wiring V2. Light emission can be performed when the anode side of the light-emitting diode LED1 is set to a high potential and the cathode side of the light-emitting diode LED1 is set to a low potential. The transistor M1 is controlled by a signal supplied to the wiring G1 and functions as a selection transistor for controlling the selection state of the circuit UT1. In addition, the transistor M2 functions as a drive transistor that controls current flowing through the light-emitting diode LED1 in accordance with a potential supplied to the gate.

When the transistor M1 is in a conduction state, a potential supplied to the wiring S1 is supplied to the gate of the transistor M2, and the emission luminance of the light-emitting diode LED1 can be controlled in accordance with the potential. The transistor M3 is controlled by a signal supplied to the wiring G2. Accordingly, a potential between the transistor M3 and the light-emitting diode LED1 can be reset to a constant potential supplied from the wiring V0, and a potential can be written to the gate of the transistor M2 in a state where a source potential of the transistor M2 is stabilized. Note that a structure where the transistor M3 is not provided can be also employed.

FIG. 7D illustrates an example of a circuit UT2 that is different from the example of the circuit UT1. The circuit UT2 has a voltage boosting function. The circuit UT2 includes a light-emitting diode LED2 (corresponding to the light-emitting diode 83), a transistor M4, a transistor M5, a transistor M6 (corresponding to the transistor 82), a transistor M7, a capacitor C2, and a capacitor C3.

A gate of the transistor M4 is electrically connected to the wiring G1, one of a source and a drain of the transistor M4 is electrically connected to a wiring S4, and the other of the source and the drain of the transistor M4 is electrically connected to one electrode of the capacitor C2, one electrode of the capacitor C3, and a gate of the transistor M6. A gate of the transistor M5 is electrically connected to a wiring G3, one of a source and a drain of the transistor M5 is electrically connected to a wiring S5, and the other of the source and the drain of the transistor M5 is electrically connected to the other electrode of the capacitor C3.

One of a source and a drain of the transistor M6 is electrically connected to the wiring V2, and the other of the source and the drain of the transistor M6 is electrically connected to an anode of the light-emitting diode LED2 and one of a source and a drain of the transistor M7. A gate of the transistor M7 is electrically connected to the wiring G2, and the other of the source and the drain of the transistor M7 is electrically connected to the wiring V0. A cathode of the light-emitting diode LED2 is electrically connected to the wiring V1.

The transistor M4 is controlled by a signal supplied to the wiring G1, and the transistor M5 is controlled by a signal supplied to the wiring G3. The transistor M6 functions as a drive transistor that controls current flowing through the light-emitting diode LED2 in accordance with a potential supplied to the gate.

The emission luminance of the light-emitting diode LED2 can be controlled in accordance with the potential supplied to the gate of the transistor M6. The transistor M7 is controlled by a signal supplied to the wiring G2. A potential between the transistor M6 and a light-emitting device EL2 can be reset to a constant potential supplied from the wiring V0, and a potential can be written to the gate of the transistor M6 in a state where a source potential of the transistor M6 is stabilized. In addition, when the potential supplied from the wiring V0 is set to the same potential as the potential of the wiring V1 or a potential lower than the potential of the wiring V1, light emission of the light-emitting diode LED2 can be suppressed.

The voltage boosting function of a pixel circuit PIX2 is described below.

First, a potential “D1” of the wiring S4 is supplied to the gate of the transistor M6 through the transistor M4, and at timing overlapping this, a reference potential “V_{ref}” is supplied to the other electrode of the capacitor C3 through the transistor M5. At this time, “D1−V_{ref}” is retained in the capacitor C3. Next, the gate of the transistor M6 is set to be floating, and a potential “D2” of the wiring S5 is supplied to the other electrode of the capacitor C3 through the transistor M5. Here, the potential “D2” is a potential for addition.

At this time, the potential of the gate of the transistor M6 is D1+(C₃/(C₃+C₂+C_{M6}))×(D2−V_{ref})), where the capacitance value of the capacitor C3 is C₃, the capacitance value of the capacitor C2 is C₂, and the capacitance value of the gate of the transistor M6 is C_{M6}. Here, assuming that the value of C₃ is sufficiently larger than the value of C₂+C_{M6}, C₃/(C₃+C₂+C_{M16}) approximates 1. Thus, it can be said that the potential of the gate of the transistor M6 approximates “D1+(D2−V_{ref}).” Then, when D1=D2 and V_{ref}=0, “D1+(D2−V_{ref}))”= “2D1.”

That is, when the circuit is designed appropriately, a potential approximately twice as high as the potential that can be input from the wiring S4 or S5 can be supplied to the gate of the transistor M6.

Owing to such action, high voltage can be generated even using a general-purpose driver IC for the source driver 92b. Thus, voltage to be input can be decreased and power consumption can be reduced.

Note that although FIG. 7C and FIG. 7D each illustrate the case where one light-emitting diode is provided in the circuit, a structure where two or more light-emitting diodes are connected in series may be employed, as illustrated in FIG. 7E1. Alternatively, a structure where two or more light-emitting diodes are connected in parallel may be employed, as illustrated in FIG. 7E2.

Alternatively, a structure where two or more light-emitting diodes connected in series are connected in parallel in two or more columns may be employed, as illustrated in FIG. 7E3. Note that transistors illustrated in FIG. 7E1 to FIG. 7E3 each correspond to the transistor M2 or the transistor M6.

When a plurality of light-emitting diodes are used as illustrated in FIG. 7E1 to FIG. 7E3, emission intensity that can be controlled by one light-emitting unit 84 can be increased. Alternatively, an emission area that can be controlled by one light-emitting unit 84 can be increased.

Note that although FIG. 7C and FIG. 7D each illustrate an example of a circuit for controlling PAM (Pulse Amplitude Modulation), luminance of the light-emitting diode may be controlled by a circuit for controlling PWM (Pulse Width Modulation).

This embodiment can be implemented in an appropriate combination with the structures described in the other embodiments.

### Embodiment 2

In this embodiment, structure examples of the liquid crystal display device will be described. Note that description similar to that in Embodiment 1 is omitted.

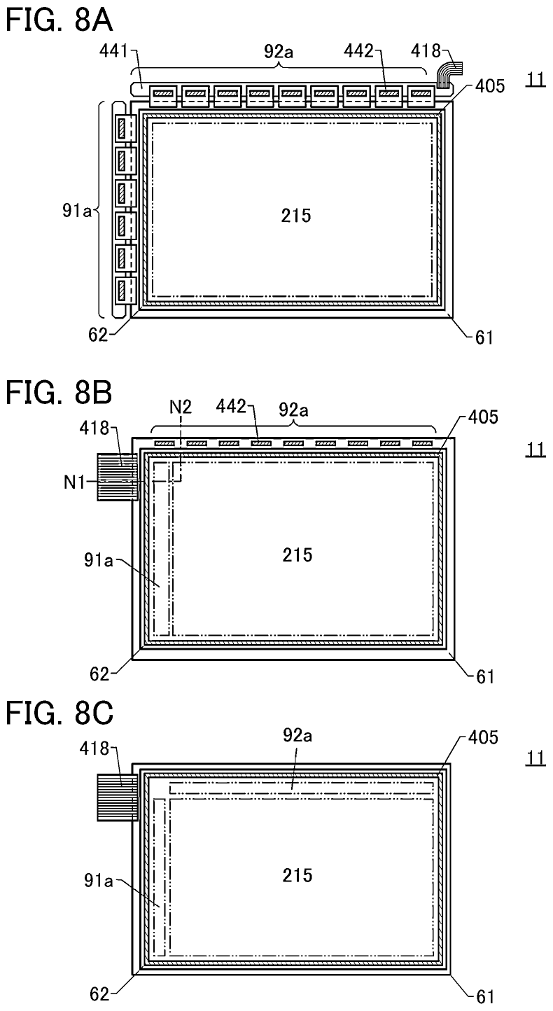

FIG. 8A to FIG. 8C are diagrams illustrating structures of the liquid crystal display device 11 according to one embodiment of the present invention.

A display portion 215 illustrated in FIG. 8A is provided with the pixel array 13 including the pixels 10 described in Embodiment 1. In addition, a sealant 405 is provided to surround the display portion 215 provided over a substrate 61, and the display portion 215 is sealed with the sealant 405 and the substrate 62.

FIG. 8A illustrates an example where each of the gate driver 91a and the source driver 92a is formed of a plurality of integrated circuits 442 provided over a printed circuit board 441. The integrated circuits 442 are IC chips that are formed using a single crystal semiconductor.

A variety of signals and potentials are supplied to the gate driver 91a and the source driver 92a through an FPC (flexible printed circuit) 418.

The integrated circuits 442 included in the gate driver 91a each have a function of supplying a selection signal to the display portion 215. The integrated circuits 442 included in the source driver 92a each have a function of supplying image data to the display portion 215. The integrated circuits 442 are mounted in regions different from a region surrounded by the sealant 405 over the substrate 61.

Note that a method for connecting the integrated circuits 442 is not particularly limited; a wire bonding method, a COG (Chip On Glass) method, a TCP (Tape Carrier Package) method, a COF (Chip On Film) method, or the like can be used.

FIG. 8B illustrates an example where the integrated circuits 442 included in the source driver 92a are mounted by a COG method. In addition, some or all of the driver circuits can be integrally formed over the same substrate as the display portion 215, so that a system-on-panel can be formed.

FIG. 8B illustrates an example where the gate driver 91a is formed over the same substrate as the display portion 215. When the driver circuits are formed concurrently with a pixel circuit in the display portion 215, the number of components can be reduced. Accordingly, productivity can be increased.

In addition, in FIG. 8B, the sealant 405 is provided to surround the display portion 215 provided over the substrate 61, and the gate driver 91a. Furthermore, the substrate 62 is provided over the display portion 215 and the gate driver 91a. Thus, the display portion 215 and the gate driver 91a are sealed together with a display element by the substrate 61, the sealant 405, and the substrate 62.

In addition, although FIG. 8B illustrates an example where the source driver 92a is separately formed and mounted on the substrate 61, one embodiment of the present invention is not limited to this structure. A gate driver may be separately formed and mounted, or part of a source driver or part of a gate driver may be separately formed and mounted. Alternatively, as illustrated in FIG. 8C, the source driver 92a may be formed over the same substrate as the display portion 215.

In some cases, the liquid crystal display device 11 includes a panel in which a display element is sealed and a module in which an IC or the like including a controller is mounted on the panel.

Transistors included in peripheral driver circuits and transistors included in the pixel circuit of the display portion may have either the same structure or different structures. The transistors included in the peripheral driver circuits may have the same structure or may use a combination of two or more kinds of structures. Similarly, the transistors included in the pixel circuit may have the same structure or may use a combination of two or more kinds of structures.

In addition, an input device can be provided over the substrate 62. A structure where the liquid crystal display device 11 illustrated in FIG. 8A to FIG. 8C is provided with the input device can function as a touch panel.

There is no particular limitation on a sensor element included in a touch panel according to one embodiment of the present invention. A variety of sensors capable of sensing approach or contact of a sensing target such as a finger and a stylus can be applied to the sensor element. For example, a variety of types such as a capacitive type, a resistive type, a surface acoustic wave type, an infrared type, an optical type, and a pressure-sensitive type can be used as a sensor type.

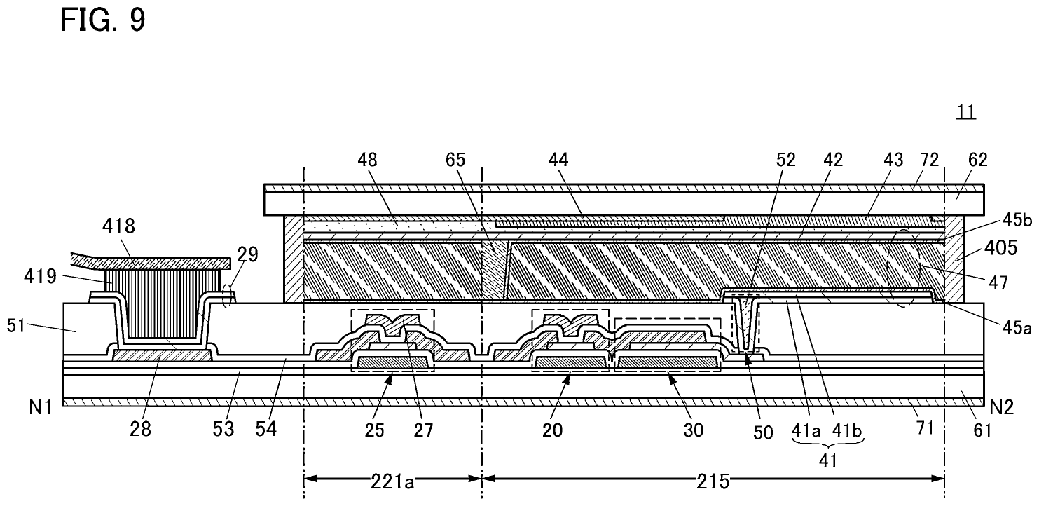

FIG. 9 is a cross-sectional view of a portion of the liquid crystal display device 11 illustrated in FIG. 8B along a line segment N1-N2.

The display portion 215 and the gate driver 91a that are provided over the substrate 61 include a plurality of transistors and the like. FIG. 9 illustrates an example of the transistor 20 and the capacitor 30 that are included in the display portion 215 and a transistor 25 that is included in the gate driver 91a. Note that in the example illustrated in FIG. 9, the transistor 20 and the transistor 25 are bottom-gate transistors but may be top-gate transistors.

The transistor 20 and the transistor 25 are provided over an insulating layer 53, and the insulating layer 51 is provided over the transistor 20 and the transistor 25.

The transistor 20 and the transistor 25 each include an electrode 27 formed over an insulating layer 54. The insulating layer 54 can function as a gate insulating film, and the electrode 27 can function as a back gate electrode.

The transistor 20 provided in the display portion 215 is electrically connected to the liquid crystal device 47. A liquid crystal device to which a variety of modes are applied can be used as the liquid crystal device 47.

For example, a liquid crystal device that employs a VA (Vertical Alignment) mode, a TN (Twisted Nematic) mode, an IPS (In-Plane Switching) mode, an ASM (Axially Symmetric aligned Micro-cell) mode, an OCB (Optically Compensated Bend) mode, an FLC (Ferroelectric Liquid Crystal) mode, an AFLC (AntiFerroelectric Liquid Crystal) mode, an ECB (Electrically Controlled Birefringence) mode, a VA-IPS mode, a guest-host mode, or the like can be used.

In addition, a normally-black liquid crystal display device, for example, a transmissive liquid crystal display device employing a vertical alignment (VA) mode may be used as the liquid crystal display device 11 described in this embodiment. An MVA (Multi-Domain Vertical Alignment) mode, a PVA (Patterned Vertical Alignment) mode, an ASV (Advanced Super View) mode, or the like can be used as the vertical alignment mode.

Note that liquid crystal device is an element that controls transmission and non-transmission of light by optical modulation action of liquid crystal. The optical modulation action of the liquid crystal is controlled by an electric field applied to the liquid crystal (including a horizontal electric field, a vertical electric field, and an oblique electric field). As the liquid crystal used for the liquid crystal device, thermotropic liquid crystal, low-molecular liquid crystal, high-molecular liquid crystal, polymer dispersed liquid crystal (PDLC), polymer network liquid crystal (PNLC), ferroelectric liquid crystal, anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Although a liquid crystal display device including a liquid crystal device with a vertical electric field mode is illustrated in the example of FIG. 9, one embodiment of the present invention can be also applied to a liquid crystal display device including a liquid crystal device with a horizontal electric field mode. In the case of employing a horizontal electric field mode, liquid crystal exhibiting a blue phase for which an alignment film is not used may be used. The blue phase is one of liquid crystal phases, which is generated immediately before a cholesteric phase changes into an isotropic phase while the temperature of cholesteric liquid crystal is increased. Since the blue phase is only generated within a narrow temperature range, a liquid crystal composition that contains a chiral material at greater than or equal to 5 wt % is used for a liquid crystal layer in order to improve the temperature range. A liquid crystal composition that contains liquid crystal exhibiting a blue phase and a chiral material has a short response time and exhibits optical isotropy. In addition, the liquid crystal composition that contains liquid crystal exhibiting a blue phase and a chiral material does not need an alignment process and has little viewing angle dependence. Furthermore, an alignment film does not need to be provided and rubbing treatment is unnecessary; therefore, electrostatic discharge damage caused by the rubbing treatment can be prevented and defects or damage of the liquid crystal display device in a manufacturing process can be reduced.

In addition, a spacer 65 is a columnar spacer that is obtained by selective etching of an insulating layer and is provided to control distance (a cell gap) between the pixel electrode 41 and the counter electrode 42. Note that a spherical spacer may be used.

The liquid crystal display device 11 includes the light-blocking layer 44, the coloring layer 43, and an insulating layer 48 between the substrate 62 and the counter electrode 42.

Examples of a material that can be used for the light-blocking layer 44 include carbon black, titanium black, a metal, a metal oxide, and a composite oxide containing a solid solution of a plurality of metal oxides. The light-blocking layer 44 may be a film containing a resin material or may be a thin film of an inorganic material such as a metal. Stacked films containing the material of the coloring layer 43 can be also used for the light-blocking layer 44. For example, a stacked-layer structure of a film containing a material used for the coloring layer 43 that transmits light of a certain color and a film containing a material used for the coloring layer 43 that transmits light of another color can be used. Material sharing between the coloring layer 43 and the light-blocking layer is preferable because process simplification as well as equipment sharing can be achieved.

Examples of a material that can be used for the coloring layer 43 include a metal material, a resin material, and a resin material containing a pigment or a dye. By using the material that is selected as appropriate, light of R (red), G (green), B (blue), or the like can be generated, so that full-color display can be performed.

Note that a color conversion layer containing a semiconductor material may be used as a substitute for the coloring layer 43. For example, light with a certain wavelength that is incident on a layer containing a nano-sized semiconductor can be converted into light with another wavelength.

A certain kind of semiconductor becomes an excited state when irradiated with light having high energy, and emits light when transferring to a stable state. In that case, the wavelength of light emitted from the semiconductor is determined by the energy gap of a semiconductor material. In a nano-sized semiconductor, an electron, a hole, or an exciton is confined to the inside of the semiconductor, which results in discrete energy states and an energy shift. Therefore, the wavelength of light emitted from the semiconductor is also changed.

Such a nano-sized semiconductor is referred to as a quantum dot. Since the amount of energy shift depends on the size of a quantum dot, adjustment of the size of the quantum dot can facilitate adjustment of an emission wavelength. In addition, the discreteness of the quantum dot restricts phase relaxation; thus, it is possible to obtain light emission having an emission spectrum with narrow peak width and high color purity. Accordingly, a color conversion layer containing a quantum dot can be used as a substitute for the coloring layer 43.

In addition, the FPC 418 for inputting a signal or power is electrically connected to an electrode 29 through an anisotropic conductive layer 419. The electrode 29 is electrically connected to a wiring 28 in an opening formed in the insulating layer 51 and the insulating layer 54. The wiring 28 is a wiring for supplying a variety of signals and potentials to be supplied to the gate driver 91a and the source driver 92a.

The electrode 29 can be formed using the same conductive layer as the pixel electrode 41 (the conductive layers 41a and 41b). In addition, the wiring 28 can be formed using the same conductive layer as source electrodes and drain electrodes of the transistor 20 and the transistor 25.

Furthermore, the polarizing plate 71 is provided on a surface of the substrate 61, and the polarizing plate 72 is provided on a surface of the substrate 62.

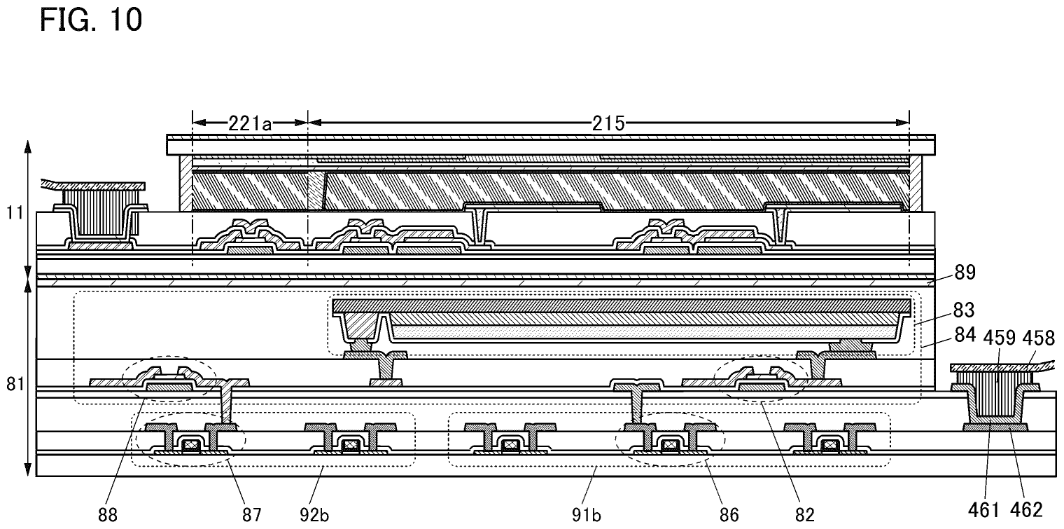

FIG. 10 is a cross-sectional view of a display device in which the structure of the backlight device 81 illustrated in FIG. 7B is combined with the liquid crystal display device 11. For each element included in the backlight device 81 and the liquid crystal display device 11, the description of FIG. 5B, FIG. 7B, and FIG. 9 can be referred to.

The gate driver 91b and the source driver 92b are placed below the light-emitting unit 84 included in the backlight device 81. Here, an example is shown in which the gate driver 91b and the source driver 92b are formed using Si transistors. Note that one or both of the gate driver 91b and the source driver 92b can be also formed using OS transistors.

Amorphous silicon, microcrystalline silicon, polycrystalline silicon, or the like can be used for a channel formation region of a Si transistor. Note that polycrystalline silicon is preferably used in the case where a transistor is provided on an insulating surface of a glass substrate or the like.

High-quality polycrystalline silicon can be easily obtained by using a laser crystallization step or the like. In addition, the high-quality polycrystalline silicon can be also obtained by a solid-phase growth method in which a metal catalyst such as nickel or palladium is added to amorphous silicon and then heated. Furthermore, to enhance crystallinity, the polycrystalline silicon formed by the solid-phase growth method using a metal catalyst may be subjected to laser irradiation. Note that the metal catalyst remains in the polycrystalline silicon and worsens electrical characteristics of the transistor; therefore, it is preferable to provide a region to which phosphorus, a noble gas, or the like is added other than the channel formation region, so that the region captures the metal catalyst.

A transistor 86 included in the gate driver 91b can be connected to a gate line included in the light-emitting unit 84. In addition, a transistor 87 included in the source driver 92b can be electrically connected to a transistor 88 included in the light-emitting unit 84. The transistor 88 corresponds to the transistor M1 illustrated in FIG. 7C or the transistor M4 illustrated in FIG. 7D.

In addition, an FPC 458 for inputting a signal or power is electrically connected to an electrode 461 through an anisotropic conductive layer 459. The electrode 461 is electrically connected to a wiring 462 in an opening formed in an insulating layer. The wiring 462 is a wiring for supplying a variety of signals and potentials to be supplied to the gate driver 91b and the source driver 92b.

The electrode 461 can be formed using the same conductive layer as the gate line included in the light-emitting unit 84. In addition, the wiring 462 can be formed using the same conductive layer as source wirings and drain wirings of the transistor 86, the transistor 87, and the like.

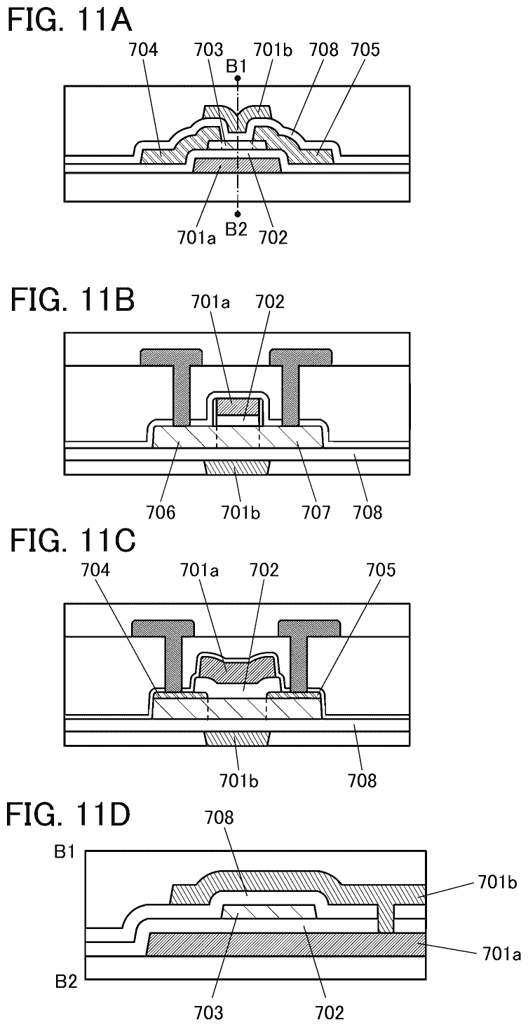

FIG. 11A shows the details of an OS transistor that can be applied to the liquid crystal display device 11 and the light-emitting unit 84. The OS transistor illustrated in FIG. 11A has a bottom-gate structure.

The OS transistor can include an oxide semiconductor layer 703, a gate electrode 701a, a gate electrode 701b, a gate insulating film 702, a gate insulating film 708, a source electrode 704, and a drain electrode 705. Note that the oxide semiconductor layer may have a structure where a plurality of semiconductor layers having different bandgaps are stacked.

Alternatively, as illustrated in FIG. 11B, the OS transistor may have a self-aligned structure where a source region 706 and a drain region 707 are formed in the oxide semiconductor layer 703 by using the gate electrode 701a as a mask.

Alternatively, as illustrated in FIG. 11C, the OS transistor may be a non-self-aligned top-gate transistor that includes a region where the gate electrode 701a overlaps each of the source electrode 704 and the drain electrode 705.

FIG. 11D is a cross-sectional view along B1-B2 illustrated in FIG. 11A. The gate electrode 701b may be electrically connected to the gate electrode 701a (a front gate) of a transistor that is oppositely provided. Such a structure can increase on-state current. In addition, a structure may be employed in which the gate electrode 701b is not connected to the gate electrode 701a and a fixed potential can be supplied to the gate electrode 701b. Such a structure can control the threshold voltage. Alternatively, a structure may be employed in which the gate electrode 701b is not provided.

In the OS transistor, a semiconductor layer has a large energy gap, and thus the OS transistor can exhibit extremely low off-state current characteristics of several yoctoamperes per micrometer (the value of current per micrometer of channel width). Owing to low off-state current, potential retention capability of a node can be increased; thus, appropriate image display can be performed even when frame frequency is decreased. For example, switching between first frame frequency (for example, higher than or equal to 60 Hz) in moving image display and second frame frequency that is lower than the first frame frequency (for example, approximately 1 to 10 Hz) in still image display can reduce power consumption of the display device.

In addition, the OS transistor has favorable saturation characteristics of drain current even when it has smaller channel length than the Si transistor; therefore, the OS transistor is suitably used as a drive transistor (the transistor 82) of the light-emitting diode 83.

As a semiconductor material used for an OS transistor, a metal oxide whose energy gap is greater than or equal to 2 eV, preferably greater than or equal to 2.5 eV, further preferably greater than or equal to 3 eV can be used. A typical example is an oxide semiconductor containing indium, and a CAAC-OS, a CAC-OS, or the like described later can be used, for example. A CAAC-OS has a crystal structure including stable atoms and is suitable for a transistor or the like that puts emphasis on reliability. In addition, a CAC-OS exhibits excellent mobility characteristics and thus is suitable for a transistor or the like that is driven at high speed.

An OS transistor has features such that impact ionization, an avalanche breakdown, a short-channel effect, and the like do not occur, which are different from those of a transistor where silicon is contained in a channel formation region (hereinafter, a Si transistor), and enables formation of a highly reliable circuit.

A semiconductor layer included in an OS transistor can be, for example, a film represented by an In-M-Zn-based oxide that contains indium, zinc, and M (a metal such as aluminum, titanium, gallium, germanium, yttrium, zirconium, lanthanum, cerium, tin, neodymium, or hafnium). The In-M-Zn-based oxide can be typically formed by a sputtering method. Alternatively, the In-M-Zn-based oxide can be formed by an ALD (Atomic layer deposition) method.

It is preferable that the atomic ratio of metal elements in a sputtering target used to form an In-M-Zn oxide by a sputtering method satisfy In≥M and Zn≥M. The atomic ratio of metal elements of such a sputtering target is preferably In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, In:M:Zn=5:1:8, or the like. Note that the atomic ratio in the deposited semiconductor layer varies from the atomic ratio of metal elements contained in the sputtering target in a range of ±40%.

An oxide semiconductor with low carrier concentration is used for the semiconductor layer. For example, for the semiconductor layer, an oxide semiconductor whose carrier concentration is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. The oxide semiconductor has low density of defect states and can be referred to as an oxide semiconductor having stable characteristics.

Note that the composition is not limited to those, and an oxide semiconductor having appropriate composition may be used depending on required semiconductor characteristics and electrical characteristics of the transistor (field-effect mobility, threshold voltage, or the like). In addition, to obtain the required semiconductor characteristics of the transistor, it is preferable that the carrier concentration, impurity concentration, defect density, atomic ratio between a metal element and oxygen, interatomic distance, density, and the like of the semiconductor layer be set to be appropriate.

When silicon or carbon, which is one of the Group 14 elements, is contained in the oxide semiconductor that constitutes the semiconductor layer, oxygen vacancies are increased, and the semiconductor layer becomes n-type. Thus, the concentration (concentration obtained by secondary ion mass spectrometry) of silicon or carbon in the semiconductor layer is set lower than or equal to 2×10¹⁸ atoms/cm³, preferably lower than or equal to 2×10¹⁷ atoms/cm³.

In addition, alkali metal and alkaline earth metal might generate carriers when bonded to an oxide semiconductor, in which case the off-state current of the transistor might be increased. Thus, the concentration (concentration obtained by secondary ion mass spectrometry) of alkali metal or alkaline earth metal in the semiconductor layer is set lower than or equal to 1×10¹⁸ atoms/cm³, preferably lower than or equal to 2×10¹⁶ atoms/cm³.

Furthermore, when nitrogen is contained in the oxide semiconductor that constitutes the semiconductor layer, electrons serving as carriers are generated and the carrier concentration is increased, so that the semiconductor layer easily becomes n-type. As a result, a transistor using an oxide semiconductor that contains nitrogen is likely to have normally-on characteristics. Therefore, the concentration (concentration obtained by secondary ion mass spectrometry) of nitrogen in the semiconductor layer is preferably set lower than or equal to 5×10¹⁸ atoms/cm³.

In addition, when hydrogen is contained in an oxide semiconductor included in the semiconductor layer, hydrogen reacts with oxygen bonded to a metal atom to be water, and thus sometimes causes an oxygen vacancy in the oxide semiconductor. When a channel formation region in the oxide semiconductor includes oxygen vacancies, the transistor sometimes has normally-on characteristics. Furthermore, in some cases, a defect that is an oxygen vacancy into which hydrogen enters functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics.

A defect in which hydrogen has entered an oxygen vacancy can function as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” described in this specification and the like can be replaced with “donor concentration” in some cases.

Therefore, hydrogen in the oxide semiconductor is preferably reduced as much as possible. Specifically, the hydrogen concentration in the oxide semiconductor that is obtained by secondary ion mass spectrometry (SIMS) is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When an oxide semiconductor with a sufficiently low concentration of impurities such as hydrogen is used for a channel formation region of a transistor, the transistor can have stable electrical characteristics.

Moreover, the semiconductor layer may have a non-single-crystal structure, for example. The non-single-crystal structure includes, for example, a CAAC-OS (C-Axis Aligned Crystalline Oxide Semiconductor) including a c-axis aligned crystal, a polycrystalline structure, a microcrystalline structure, or an amorphous structure. Among the non-single-crystal structures, the amorphous structure has the highest density of defect states, whereas the CAAC-OS has the lowest density of defect states.

An oxide semiconductor film having an amorphous structure has disordered atomic arrangement and no crystalline component, for example. Moreover, an oxide film having an amorphous structure has a completely amorphous structure and no crystal part, for example.

Note that the semiconductor layer may be a mixed film including two or more kinds selected from a region having an amorphous structure, a region having a microcrystalline structure, a region having a polycrystalline structure, a CAAC-OS region, and a region having a single crystal structure. The mixed film has, for example, a single-layer structure or a stacked-layer structure including two or more kinds of regions selected from the above regions in some cases.

The composition of a CAC (Cloud-Aligned Composite)-OS, which is one embodiment of a non-single-crystal semiconductor layer, will be described below.

The CAC-OS is, for example, a composition of a material in which elements that constitute an oxide semiconductor are unevenly distributed to have a size greater than or equal to 0.5 nm and less than or equal to 10 nm, preferably greater than or equal to 1 nm and less than or equal to 2 nm, or a similar size. Note that in the following description, a state in which one or more metal elements are unevenly distributed and regions including the metal element(s) are mixed to have a size greater than or equal to 0.5 nm and less than or equal to 10 nm, preferably greater than or equal to 1 nm and less than or equal to 2 nm, or a similar size in an oxide semiconductor is referred to as a mosaic pattern or a patch-like pattern.

Note that the oxide semiconductor preferably contains at least indium. In particular, indium and zinc are preferably contained. Moreover, in addition to these, one kind or a plurality of kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, a CAC-OS in an In—Ga—Zn oxide (an In—Ga—Zn oxide in the CAC-OS may be particularly referred to as CAC-IGZO) has a composition in which materials are separated into indium oxide (hereinafter referred to as InO_{X1} (X1 is a real number greater than 0)) or indium zinc oxide (hereinafter referred to as In_{X2}Zn_{Y2}O_{Z2} (each of X2, Y2, and Z2 is a real number greater than 0)) and gallium oxide (hereinafter referred to as GaO_{X3} (X3 is a real number greater than 0)), gallium zinc oxide (hereinafter referred to as Ga_{X4}Zn_{Y4}O_{Z4} (each of X4, Y4, and Z4 is a real number greater than 0)), or the like so that a mosaic pattern is formed, and mosaic-like InO_{X1} or In_{X2}Zn_{Y2}O_{Z2} is evenly distributed in the film (this composition is hereinafter also referred to as a cloud-like composition).

That is, the CAC-OS is a composite oxide semiconductor having a composition in which a region where GaO_{X3} is a main component and a region where In_{X2}Zn_{Y2}O_{Z2} or InO_{X1} is a main component are mixed. Note that in this specification, for example, when the atomic ratio of In to an element M in a first region is larger than the atomic ratio of In to the element M in a second region, the first region is regarded as having a higher In concentration than the second region.

Note that IGZO is a commonly known name and sometimes refers to one compound formed of In, Ga, Zn, and O. A typical example is a crystalline compound represented by InGaO₃(ZnO)ₘ₁ (m1 is a natural number) or In₍₁₊ₓ₀₎Ga₍₁₋ₓ₀₎ O₃(ZnO)ₘ₀ (−1≤x0≤1; m0 is a given number).

The crystalline compound has a single crystal structure, a polycrystalline structure, or a CAAC structure. Note that the CAAC structure is a crystal structure in which a plurality of IGZO nanocrystals have c-axis alignment and are connected in an a-b plane without alignment.

Meanwhile, the CAC-OS relates to the material composition of an oxide semiconductor. In the material composition of a CAC-OS containing In, Ga, Zn, and O, some regions that contain Ga as a main component and are observed as nanoparticles and some regions that contain In as a main component and are observed as nanoparticles are each randomly dispersed in a mosaic pattern. Therefore, the crystal structure is a secondary element for the CAC-OS.

Note that the CAC-OS is regarded as not including a stacked-layer structure of two or more kinds of films with different compositions. For example, a two-layer structure of a film containing In as a main component and a film containing Ga as a main component is not included.

Note that a clear boundary between the region where GaO_{X3} is a main component and the region where In_{X2}Zn_{Y2}O_{Z2} or InO_{X1} is a main component cannot be observed in some cases.

Note that in the case where one kind or a plurality of kinds selected from aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium, the CAC-OS refers to a composition in which some regions that contain the metal element(s) as a main component and are observed as nanoparticles and some regions that contain In as a main component and are observed as nanoparticles are each randomly dispersed in a mosaic pattern.

The CAC-OS can be formed by a sputtering method under a condition where a substrate is not heated intentionally, for example. In addition, in the case of forming the CAC-OS by a sputtering method, one or more selected from an inert gas (typically, argon), an oxygen gas, and a nitrogen gas may be used as a deposition gas. Furthermore, the ratio of the flow rate of an oxygen gas to the total flow rate of the deposition gas at the time of deposition is preferably as low as possible, and for example, the ratio of the flow rate of the oxygen gas is preferably higher than or equal to 0% and lower than 30%, further preferably higher than or equal to 0% and lower than or equal to 10%.

The CAC-OS is characterized in that no clear peak is observed at the time of measurement using θ/2θ scan by an Out-of-plane method, which is one of the X-ray diffraction (XRD) measurement methods. That is, it is found from X-ray diffraction measurement that no alignment in an a-b plane direction and a c-axis direction is observed in a measured region.

In addition, in an electron diffraction pattern of the CAC-OS that is obtained by irradiation with an electron beam with a probe diameter of 1 nm (also referred to as a nanobeam electron beam), a ring-like high-luminance region and a plurality of bright spots in the ring-like region are observed. It is therefore found from the electron diffraction pattern that the crystal structure of the CAC-OS includes an nc (nano-crystal) structure with no alignment in a plan-view direction and a cross-sectional direction.

Moreover, for example, it can be confirmed by EDX mapping obtained using energy dispersive X-ray spectroscopy (EDX) that the CAC-OS in the In—Ga—Zn oxide has a composition in which regions where GaO_{X3} is a main component and regions where In_{X2}Zn_{Y2}O_{Z2} or InO_{X1} is a main component are unevenly distributed and mixed.

The CAC-OS has a composition different from that of an IGZO compound in which metal elements are evenly distributed, and has characteristics different from those of the IGZO compound. That is, the CAC-OS has a composition in which regions where GaO_{X3} or the like is a main component and regions where In_{X2}Zn_{Y2}O_{Z2} or InO_{X1} is a main component are phase-separated from each other, and the regions including the respective elements as the main components form a mosaic pattern.

Here, a region where In_{X2}Zn_{Y2}O_{Z2} or InO_{X1} is a main component is a region whose conductivity is higher than that of a region where GaO_{X3} or the like is a main component. In other words, when carriers flow through regions where In_{X2}Zn_{Y2}O_{Z2} or InO_{X1} is a main component, the conductivity of an oxide semiconductor is exhibited. Accordingly, when the regions where In_{X2}Zn_{Y2}O_{Z2} or InO_{X1} is a main component are distributed like a cloud in an oxide semiconductor, high field-effect mobility (u) can be achieved.

In contrast, a region where GaO_{X3} or the like is a main component is a region whose insulating property is higher than that of a region where In_{X2}Zn_{Y2}O_{Z2} or InO_{X1} is a main component. In other words, when regions where GaO_{X3} or the like is a main component are distributed in an oxide semiconductor, leakage current can be suppressed and favorable switching operation can be achieved.

Accordingly, when the CAC-OS is used for a semiconductor device, the insulating property derived from GaO_{X3} or the like and the conductivity derived from In_{X2}Zn_{Y2}O_{Z2} or InO_{X1} complement each other, so that high on-state current (Iₒₙ) and high field-effect mobility (μ) can be achieved.

In addition, a semiconductor device using the CAC-OS has high reliability. Thus, the CAC-OS is suitable for a constituent material of a variety of semiconductor apparatuses.

This embodiment can be implemented in an appropriate combination with the structures described in the other embodiments and the like.

### Embodiment 3

Examples of an electronic device that can use the display device according to one embodiment of the present invention include display devices, personal computers, image memory devices or image reproducing devices provided with storage media, cellular phones, game machines including portable game machines, portable data terminals, e-book readers, cameras such as video cameras and digital cameras, goggle-type displays (head mounted displays), navigation systems, audio reproducing devices (car audio players, digital audio players, and the like), copiers, facsimiles, printers, multifunction printers, automated teller machines (ATM), and vending machines.

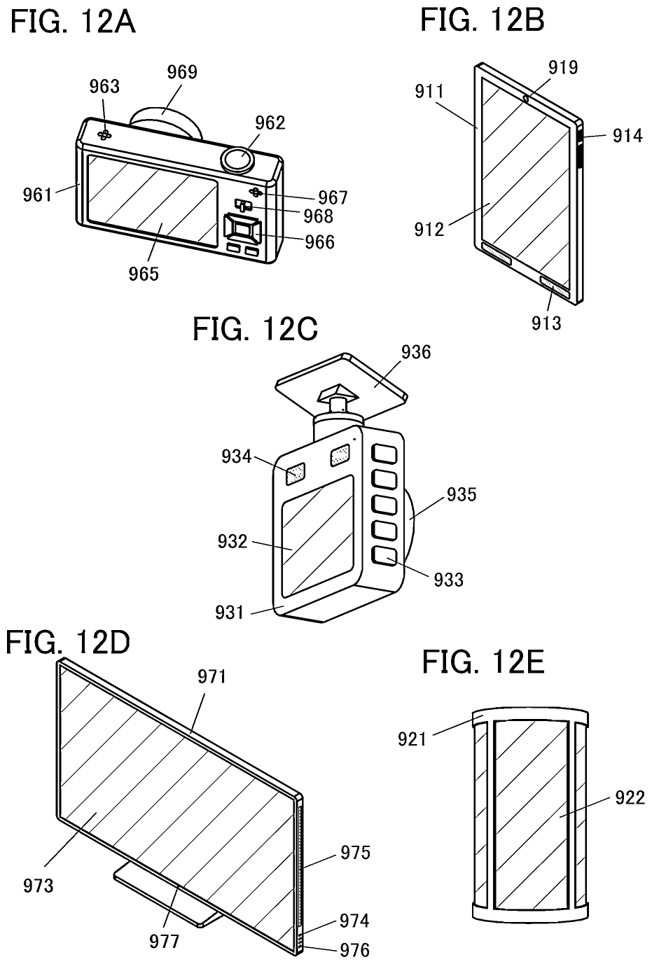

FIG. 12A illustrates a digital camera, which includes a housing 961, a shutter button 962, a microphone 963, a speaker 967, a display portion 965, operation keys 966, a zoom lever 968, a lens 969, and the like. The display device according to one embodiment of the present invention can be used for the display portion 965.

FIG. 12B illustrates a portable data terminal, which includes a housing 911, a display portion 912, speakers 913, an operation button 914, a camera 919, and the like. A touch panel function of the display portion 912 enables input and output of information. The display device according to one embodiment of the present invention can be used for the display portion 912.

FIG. 12C illustrates a dashboard camera, which includes a housing 931, a display portion 932, operation buttons 933, microphones 934, a lens 935, an attaching member 936, and the like. The dashboard camera is fixed to the windshield or the like of a motor vehicle by the attaching member 936 so that the dashboard camera can record a front view during driving. An image being recorded can be displayed on the display portion 932. The display device according to one embodiment of the present invention can be employed for the display portion 932.

FIG. 12D illustrates a television, which includes a housing 971, a display portion 973, operation buttons 974, speakers 975, communication connection terminals 976, an optical sensor 977, and the like. The display portion 973 is provided with a touch sensor, and an input operation can be also performed. The display device according to one embodiment of the present invention can be used for the display portion 973.

FIG. 12E illustrates digital signage, which has a large display portion 922. The large display portion 922 in the digital signage is attached to a side surface of a pillar 921, for example. The display device according to one embodiment of the present invention can be used for the display portion 922.

This embodiment can be implemented in an appropriate combination with the structures described in the other embodiments.

### REFERENCE NUMERALS

10: pixel, 11: liquid crystal display device, 13: pixel array, 20: transistor, 21: wiring, 22: wiring, 23: semiconductor layer, 25: transistor, 27: electrode, 28: wiring, 29: electrode, 30: capacitor, 31: wiring, 32: insulating layer, 33: wiring, 34: wiring, 40x: alignment defect region, 40: liquid crystal layer, 41a: conductive layer, 41b: conductive layer, 41: pixel electrode, 42: counter electrode, 43: coloring layer, 44: light-blocking layer, 45a: alignment film, 45b: alignment film, 47: liquid crystal device, 48: insulating layer, 50: opening portion, 51: insulating layer, 52: insulating layer, 53: insulating layer, 54: insulating layer, 61: substrate, 62: substrate, 65: spacer, 71: polarizing plate, 72: polarizing plate, 81: backlight device, 82: transistor, 83: light-emitting diode, 84: light-emitting unit, 85: LED array, 86: transistor, 87: transistor, 88: transistor, 89: color conversion layer, 91a: gate driver, 91b: gate driver, 92a: source driver, 92b: source driver, 215: display portion, 405: sealant, 418: FPC, 419: anisotropic conductive layer, 441: printed circuit board, 442: integrated circuit, 458: FPC, 459: anisotropic conductive layer, 461: electrode, 462: wiring, 701a: gate electrode, 701b: gate electrode, 702: gate insulating film, 703: oxide semiconductor layer, 704: source electrode, 705: drain electrode, 706: source region, 707: drain region, 708: gate insulating film, 911: housing, 912: display portion, 913: speaker, 914: operation button, 919: camera, 921: pillar, 922: display portion, 931: housing, 932: display portion, 933: operation button, 934: microphone, 935: lens, 936: attaching member, 961: housing, 962: shutter button, 963: microphone, 965: display portion, 966: operation key, 967: speaker, 968: zoom lever, 969: lens, 971: housing, 973: display portion, 974: operation button, 975: speaker, 976: communication connection terminal, and 977: optical sensor.

1. A display device comprising:
a first transistor;
a first conductive layer;
a second conductive layer;
a third conductive layer;
a first insulating layer;
a second insulating layer;
an alignment film; and
a liquid crystal layer,
wherein the first transistor is electrically connected to the first conductive layer,
wherein the first insulating layer is provided over the first transistor and the first conductive layer,
wherein the first insulating layer comprises an opening portion penetrating the first insulating layer in a region overlapping the first conductive layer,
wherein the second conductive layer is provided to be in contact with a top surface of the first insulating layer, a side surface of the opening portion, and the first conductive layer exposed to a bottom portion of the opening portion,
wherein the second insulating layer is provided to be in contact with the second conductive layer to fill a step caused by the opening portion,
wherein the third conductive layer is provided to be in contact with the second conductive layer and the second insulating layer,
wherein the alignment film is provided over the first insulating layer, the second conductive layer, and the third conductive layer,
wherein the liquid crystal layer is provided over the alignment film, and
wherein the first conductive layer, the second conductive layer, the third conductive layer, the first insulating layer, and the second insulating layer each have a property of transmitting visible light.

2. The display device according to claim 1,
wherein a light-blocking layer is provided over the liquid crystal layer,
wherein in a plan view, the light-blocking layer comprises a region overlapping the first transistor, and
wherein in the plan view, the light-blocking layer does not comprise a region overlapping the opening portion.

3. The display device according to claim 1, further comprising;
a semiconductor layer,
wherein the semiconductor layer comprises a channel formation region of the first transistor,
wherein the first conductive layer comprises a metal oxide, and
wherein the first conductive layer is electrically connected to the semiconductor layer through a metal layer.

4. The display device according to claim 3, wherein the first conductive layer and the metal layer are configured to function as one electrode of a capacitor.

5. The display device according to claim 3, wherein the semiconductor layer comprises a metal oxide.

6. The display device according to claim 1, further comprising:
a backlight device,
wherein the backlight device comprises a light-emitting diode.

7. The display device according to claim 6,
wherein light emitted from the light-emitting diode is blue light,
wherein a color conversion layer is provided over the light-emitting diode, and
wherein the backlight device emits white light.

8. The display device according to claim 7, wherein the color conversion layer comprises a quantum dot.

9. The display device according to claim 6, further comprising:
a driver circuit,
wherein the light-emitting diode is electrically connected to a second transistor,
wherein the driver circuit is configured to drive the second transistor, and
wherein, when seen from a direction perpendicular to a top surface of a substrate over which the driver circuit is formed, at least part of the driver circuit overlaps the light-emitting diode.

10. The display device according to claim 9,
wherein the second transistor comprises a metal oxide in a channel formation region, and
wherein a third transistor included in the driver circuit comprises silicon in a channel formation region.

11. The display device according to claim 6, wherein the light-emitting diode is a mini LED or a micro LED.

12. An electronic device comprising:
the display device according to claim 1; and
a camera.

13. A display device comprising:
a first transistor;
a first conductive layer;
a second conductive layer;
a third conductive layer;
a first insulating layer;
a second insulating layer;
an alignment film; and
a liquid crystal layer,
wherein the first transistor is electrically connected to the first conductive layer,
wherein the first insulating layer is provided over the first transistor and the first conductive layer,
wherein the first insulating layer comprises an opening portion penetrating the first insulating layer in a region overlapping the first conductive layer,
wherein the second conductive layer is provided to be in contact with a top surface of the first insulating layer, a side surface of the opening portion, and a top surface of the first conductive layer,
wherein the second insulating layer is provided to be in contact with the second conductive layer,
wherein the third conductive layer is provided to be in contact with the second conductive layer and the second insulating layer,
wherein the alignment film is provided over the first insulating layer, the second conductive layer, and the third conductive layer,
wherein the liquid crystal layer is provided over the alignment film, and
wherein the first conductive layer, the second conductive layer, the third conductive layer, the first insulating layer, and the second insulating layer each have a property of transmitting visible light.
